(19) United States
(12) Patent Application Publication
(10) Pub. No.: US 2020/0245499 A1
(43) Pub. Date: Jul. 30, 2020

(54) Heat Dissipation Structure, Cabinet, And Communications System

(71) Applicant: HUAWEI TECHNOLOGIES CO., LTD., Shenzhen (CN)

(72) Inventors: Jiang LI, Dongguan (CN); Jun WANG, Dongguan (CN); Lirui JIA, Dongguan (CN)

(21) Appl. No.: 16/849,445

(22) Filed: Apr. 15, 2020

Related U.S. Application Data
(63) Continuation of application No. PCT/CN2018/110259, filed on Oct. 15, 2018.

(30) Foreign Application Priority Data
Oct. 16, 2017 (CN) 201710958161.5
Nov. 29, 2017 (CN) 201721628701.5

(51) Int. Cl. H05K 7/20

(52) U.S. Cl. CPC H05K 7/20145; H05K 7/20172

(57) ABSTRACT

A heat dissipation structure is disclose, the structure includes a housing, a first air vent and a second air vent. There is a gap between two neighboring side panels, and the 2N inner-layer side panels are grouped into N groups of inner-layer side panels in an arrangement sequence. A first gap between a first inner-layer and an outer-layer side panel communicates with the inside of the cabinet, or a first gap between two neighboring inner-layer side panels in different groups and a first gap between a first inner-layer and the outer-layer side panel communicate with each other, and communicate with the inside of the cabinet, to form an internal circulation ventilation channel. Second gaps, each of which is between two inner-layer side panels in a same group, communicate with each other, and communicate with the first and the second air vent, to form an external circulation ventilation channel.

### CROSS-REFERENCE TO RELATED APPLICATIONS

This application is a continuation of International Application No. PCT/CN2018/110259, filed on Oct. 15, 2018, which claims priority to Chinese Patent Application No. 201721628701.5, filed on Nov. 29, 2017 and Chinese Patent Application No. 201710958161.5, filed on Oct. 16, 2017. The disclosures of the aforementioned applications are hereby incorporated by reference in their entireties.

### TECHNICAL FIELD

This application relates to the field of heat dissipation technologies, and in particular, to a heat dissipation structure, a cabinet, and a communications system.

### BACKGROUND

To ensure that an electronic device mounted inside a cabinet can work normally and reliably within an allowable operating temperature range, the cabinet needs to have a particular heat dissipation function, to transfer heat generated by the electronic device to the outside of the cabinet.

In the prior art, heat may be dissipated for the electronic device inside the cabinet in the following manner. Specifically, as shown in FIG. 1, the cabinet includes three layers of side panels, which may be sequentially denoted as a side panel a, a side panel b, and a side panel c in descending order of distances from the electronic device. A gap between the side panel a and the side panel b communicates with the outside of the cabinet to form an external circulation ventilation channel, and a gap between the side panel c and the side panel b communicates with an air intake vent and an air exhaust vent of the electronic device to form an internal circulation ventilation channel. Both the internal circulation ventilation channel and the external circulation ventilation channel transfer heat generated by the electronic device to the outside of the cabinet by using a same side panel (namely, the side panel b).

However, in the prior art, because both the internal circulation ventilation channel and the external circulation ventilation channel transfer the heat generated by the electronic device to the outside of the cabinet by using the same side panel, heat dissipation efficiency is low.

### SUMMARY

This application provides a heat dissipation structure, a cabinet, and a communications system, to resolve a prior-art problem of low heat dissipation efficiency caused because both an internal circulation ventilation channel and an external circulation ventilation channel transfer heat generated by an electronic device to the outside of a cabinet by using a same side panel.

This application provides a heat dissipation structure, configured to dissipate heat for an electronic device mounted inside a cabinet, and including a housing of the cabinet.

A first air vent and a second air vent that have different heights are disposed on the housing, and both the first air vent and the second air vent communicate with the outside of the cabinet.

The housing includes 2N+1 layers of side panels, the 2N+1 layers of side panels include an outer-layer side panel and 2N inner-layer side panels, there is a gap between two neighboring side panels, and the 2N inner-layer side panels are grouped into N groups of inner-layer side panels in an arrangement sequence, where N is a positive integer.

When N is equal to 1, a first gap between a first inner-layer side panel and the outer-layer side panel communicates with the inside of the cabinet, to form an internal circulation ventilation channel.

When N is greater than 1, a first gap between two neighboring inner-layer side panels in different groups and a first gap between the first inner-layer side panel and the outer-layer side panel communicate with each other, and communicate with the inside of the cabinet, to form an internal circulation ventilation channel, and the first inner-layer side panel is an inner-layer side panel that is the farthest from the electronic device in the 2N inner-layer side panels.

Second gaps, each of which is between two inner-layer side panels in a same group, communicate with each other, and communicate with the first air vent and the second air vent, to form an external circulation ventilation channel.

According to the heat dissipation structure provided in the first aspect, when N=1, a first gap between an inner-layer side panel that is farther from the electronic device in two inner-layer side panels and the outer-layer side panel communicates with the inside of the cabinet, to form an internal circulation ventilation channel; and a second gap between the two inner-layer side panels communicates with the first air vent and the second air vent, and both the first air vent and the second air vent communicate with the outside of the cabinet, to form an external circulation ventilation channel, so that the external circulation ventilation channel is disposed on an inner side of the internal circulation ventilation channel, to additionally increase a heat exchange area when sizes of the side panels of the cabinet are determined. Compared with a heat dissipation structure that is in the prior art and that dissipates heat by using only a heat exchange area provided by an intermediate-layer side panel in three layers of side panels, in the heat dissipation structure provided in this embodiment of this application, all the layers of side panels can provide heat dissipation areas, to improve heat dissipation efficiency.

In addition, when N is greater than 1, the 2N inner-layer side panels are grouped into the N groups of inner-layer side panels in the arrangement sequence, and the first gap between the two neighboring inner-layer side panels in the different groups and the first gap between the first inner-layer side panel and the outer-layer side panel communicate with each other, and communicate with the inside of the cabinet, to form the internal circulation ventilation channel; and the second gap between two inner-layer side panels in one group and the second gap between two inner-layer side panels in another group communicate with each other, and communicate with the first air vent and the second air vent, and both the first air vent and the second air vent communicate with the outside of the cabinet, to form the external circulation ventilation channel, so that when a heat exchange area provided by 2+1 layers of side panels cannot meet a heat dissipation requirement, an even quantity of inner-layer side panels may be added, to further improve a heat dissipation capability.

In addition, because the heat dissipation structure provided in this embodiment of this application can improve heat dissipation efficiency without using an extra heat exchange component, the heat dissipation structure provided in this embodiment of this application can reduce costs. Further, because the heat dissipation structure provided in this embodiment of this application can improve heat dissipation efficiency without changing the sizes of the side panels of the cabinet, the heat dissipation structure provided in this embodiment of this application can ensure consistency of appearance of the cabinet.

In a possible implementation, the heat dissipation structure further includes air blocking panels and tubular air deflection structures.

The air blocking panels are disposed between upper ends of two side panels forming the first gap and between lower ends of the two side panels forming the first gap.

A first through hole and a second through hole that have different heights are disposed on each inner-layer side panel, a first through hole and a second through hole that are disposed on a second inner-layer side panel separately communicate with the inside of the cabinet, and the second inner-layer side panel is an inner-layer side panel that is the closest to the electronic device in the 2N inner-layer side panels.

The air deflection structure is connected between first through holes of two inner-layer side panels in a same group, and the air deflection structure is connected between second through holes of the two inner-layer side panels in the same group.

According to the heat dissipation structure provided in the first aspect, the air blocking panels are disposed between the upper ends of the two side panels forming the first gap and between the lower ends of the two side panels forming the first gap, the first through hole and the second through hole that have different heights are disposed on each inner-layer side panel, the first through hole and the second through hole that are disposed on the second inner-layer side panel separately communicate with the inside of the cabinet, the second inner-layer side panel is an inner-layer side panel that is the closest to the electronic device in the 2N inner-layer side panels, the air deflection structure is connected between the first through holes of the two inner-layer side panels in the same group, and the air deflection structure is connected between the second through holes of the two inner-layer side panels in the same group, so that when N is equal to 1, the first gap between the first inner-layer side panel and the outer-layer side panel communicates with the inside of the cabinet, or when N is greater than 1, the first gap between the two neighboring inner-layer side panels in the different groups and the first gap between the first inner-layer side panel and the outer-layer side panel communicate with each other, and communicate with the inside of the cabinet, to form the internal circulation ventilation channel.

In a possible implementation, the first air vent is disposed on a top panel of the housing, and the second air vent is disposed on a bottom panel and/or the outer-layer side panel of the housing; or

the first air vent is disposed on the outer-layer side panel of the housing, and the second air vent is disposed on a bottom panel and/or the outer-layer side panel of the housing.

In a possible implementation, the air blocking panels include the top panel and/or the bottom panel of the housing.

In a possible implementation, the heat dissipation structure further includes air blocking panels.

The air blocking panels are disposed between upper ends of two inner-layer side panels forming the second gap and between lower ends of the two inner-layer side panels forming the second gap.

There is a third gap between upper ends of side panels forming the first gap and a top panel of the housing, there is a fourth gap between lower ends of the side panels forming the first gap and a bottom panel of the housing, and both the third gap and the fourth gap communicate with the inside of the cabinet.

According to the heat dissipation structure provided in the first aspect, the air blocking panels are disposed between the upper ends of the two inner-layer side panels forming the second gap and between the lower ends of the two inner-layer side panels forming the second gap, there is the third gap between the upper ends of the side panels forming the first gap and the top panel of the housing, there is the fourth gap between the lower ends of the side panels forming the first gap and the bottom panel of the housing, and both the third gap and the fourth gap communicate with the inside of the cabinet, so that when N is equal to 1, the first gap between the first inner-layer side panel and the outer-layer side panel communicates with the inside of the cabinet, or when N is greater than 1, the first gap between the two neighboring inner-layer side panels in the different groups and the first gap between the first inner-layer side panel and the outer-layer side panel communicate with each other, and communicate with the outside of the cabinet, to form the internal circulation ventilation channel.

In a possible implementation, both the first air vent and the second air vent are disposed on the outer-layer side panel, and the heat dissipation structure further includes tubular air deflection structures.

A third through hole and a fourth through hole that have different heights are disposed on an inner-layer side panel other than a second inner-layer side panel in the 2N inner-layer side panels, and the second inner-layer side panel is an inner-layer side panel that is the closest to the electronic device in the 2N inner-layer side panels.

When N is equal to 1, the air deflection structure is connected between a third through hole of the first inner-layer side panel and the first air vent, and the air deflection structure is connected between a fourth through hole of the first inner-layer side panel and the second air vent.

When N is greater than 1, the air deflection structure is connected between a third through hole of the first inner-layer side panel and the first air vent, the air deflection structure is connected between a fourth through hole of the first inner-layer side panel and the second air vent, the air deflection structure is connected between third through holes of two neighboring inner-layer side panels in different groups, and the air deflection structure is connected between fourth through holes of the two neighboring inner-layer side panels in the different groups.

According to the heat dissipation structure provided in the first aspect, when N is equal to 1, cold air outside the cabinet may be led into the second gap between the two inner-layer side panels in the same group through the air deflection structure disposed between the fourth through hole of the first inner-layer side panel and the second air vent; and after being heated by the inner-layer side panels, the air is led out through the air deflection structure disposed between the third through hole of the first inner-layer side panel and the first air vent.

According to the heat dissipation structure provided in the first aspect, when N is greater than 1, cold air outside the cabinet may be led into the second gap between the two inner-layer side panels in the same group through the air deflection structure disposed between the fourth through hole of the first inner-layer side panel and the second air vent and the air deflection structure disposed between the fourth through holes of the two neighboring inner-layer side panels in the different groups; and after being heated by the inner-layer side panels, the air is led out through the air deflection structure disposed between the third through hole of the first inner-layer side panel and the first air vent and the air deflection structure disposed between the third through holes of the two neighboring inner-layer side panels in the different groups.

In a possible implementation, the heat dissipation structure further includes a fan disposed in the external circulation ventilation channel.

According to the heat dissipation structure provided in the first aspect, the fan is disposed in the external circulation ventilation channel, so that a flow velocity of air in the external circulation ventilation channel can be greatly increased, and heat dissipation efficiency can be further improved.

In a possible implementation, the side panels include smooth panels or corrugated panels.

In a possible implementation, gilled structures or flow disturbing structures are further disposed on the side panels.

According to the heat dissipation structure provided in the first aspect, the gilled structures or the flow disturbing structures are disposed on the side panels, so that heat dissipation capabilities of the side panels themselves can be improved, and heat dissipation efficiency can be further improved.

According to a second aspect, this application provides a cabinet, including a fan and the heat dissipation structure described in any possible implementation of the first aspect, where the fan is disposed in an internal circulation ventilation channel of the heat dissipation structure.

According to the cabinet provided in the second aspect, when N is equal to 1, a first gap between an inner-layer side panel that is farther from an electronic device in two inner-layer side panels and an outer-layer side panel communicates with the inside of the cabinet, to form the internal circulation ventilation channel; and a second gap between the two inner-layer side panels communicates with a first air vent and a second air vent, and both the first air vent and the second air vent communicate with the outside of the cabinet, to form an external circulation ventilation channel, so that the external circulation ventilation channel is disposed on an inner side of the internal circulation ventilation channel, to additionally increase a heat exchange area when sizes of side panels of the cabinet are determined. Compared with a heat dissipation structure that is in the prior art and that dissipates heat by using only a heat exchange area provided by an intermediate-layer side panel in three layers of side panels, in the cabinet provided in this embodiment of this application, all layers of side panels can provide heat dissipation areas, to improve heat dissipation efficiency of the cabinet.

In addition, when N is greater than 1, 2N inner-layer side panels are grouped into N groups of inner-layer side panels in an arrangement sequence, a first gap between two neighboring inner-layer side panels in different groups and a first gap between a first inner-layer side panel and an outer-layer side panel communicate with each other, and communicate with the inside of the cabinet, to form the internal circulation ventilation channel; and second gaps, each of which is between two inner-layer side panels in a same group, communicate with each other, and communicate with a first air vent and a second air vent, and both the first air vent and the second air vent communicate with the outside of the cabinet, to form an external circulation ventilation channel, so that when a heat exchange area provided by 2+1 layers of side panels cannot meet a heat dissipation requirement, an even quantity of inner-layer side panels may be added, to further improve a heat dissipation capability of the cabinet.

In addition, because the cabinet provided in this embodiment of this application can improve heat dissipation efficiency without using an extra heat exchange component, costs are reduced. Further, because the cabinet provided in this embodiment of this application can improve heat dissipation efficiency without changing the sizes of the side panels of the cabinet, consistency of appearance of the cabinet is ensured.

According to a third aspect, this application provides a communications system, including the cabinet described in the second aspect and an electronic device mounted inside the cabinet.

### BRIEF DESCRIPTION OF DRAWINGS

FIG. 1 is a schematic structural diagram of a heat dissipation structure in the prior art;

FIG. 2A is a first schematic structural diagram of a heat dissipation structure according to an embodiment of this application;

FIG. 2B is a second schematic structural diagram of a heat dissipation structure according to an embodiment of this application;

FIG. 3A is a main view of a heat dissipation structure according to another embodiment of this application;

FIG. 3B is a top view of the heat dissipation structure according to the another embodiment of this application;

FIG. 4 is a schematic structural diagram of a heat dissipation structure according to still another embodiment of this application;

FIG. 5 is a schematic structural diagram of a heat dissipation structure according to still another embodiment of this application;

FIG. 6A is a main view of a heat dissipation structure according to still another embodiment of this application;

FIG. 6B is a top view of the heat dissipation structure according to the still another embodiment of this application; and

FIG. 7 is a schematic structural diagram of a heat dissipation structure according to still another embodiment of this application.

### DETAILED DESCRIPTION OF EMBODIMENTS

Embodiments of this application provide a heat dissipation structure, to dissipate heat for an electronic device mounted inside a cabinet.

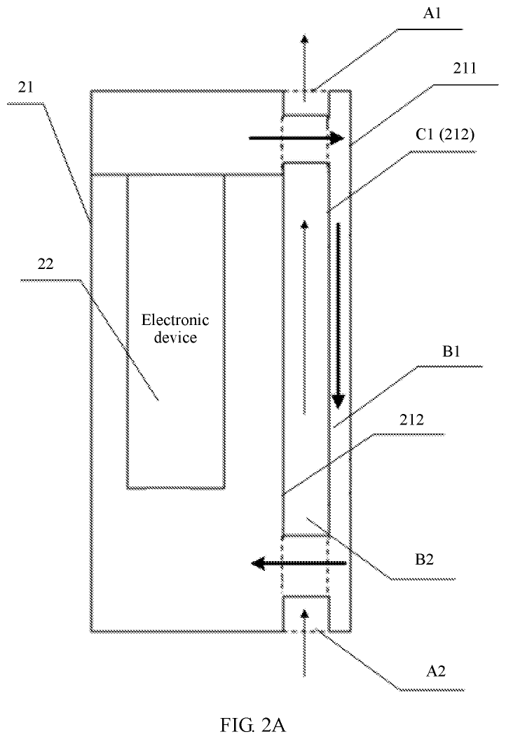

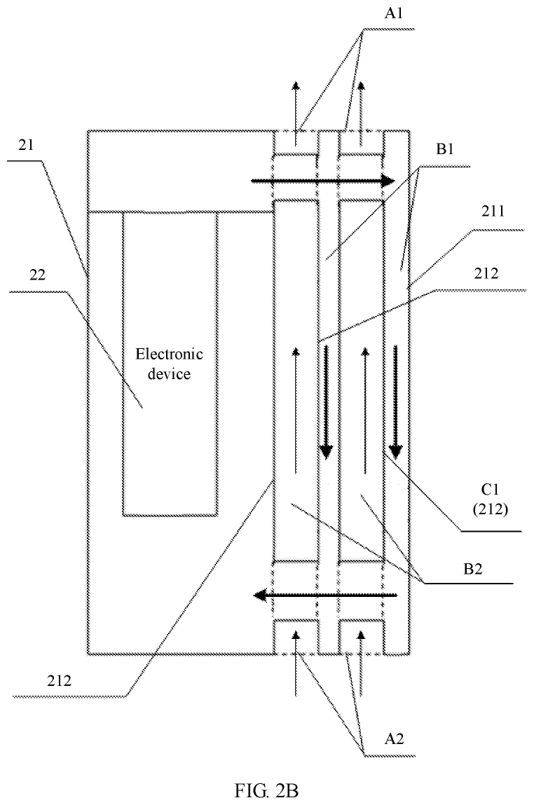

FIG. 2A is a first schematic structural diagram of a heat dissipation structure according to an embodiment of this application, and FIG. 2B is a second schematic structural diagram of a heat dissipation structure according to an embodiment of this application. The heat dissipation structure provided in this embodiment is configured to dissipate heat for an electronic device 22 mounted inside a cabinet 21. As shown in FIG. 2A and FIG. 2B, the heat dissipation structure in the embodiments may include a housing of the cabinet 21.

A first air vent A1 and a second air vent A2 that have different heights are disposed on the housing, and both the first air vent A1 and the second air vent A2 communicate with the outside of the cabinet 21.

The housing includes 2N+1 layers of side panels, the 2N+1 layers of side panels include an outer-layer side panel 211 and 2N inner-layer side panels 212, there is a gap between two neighboring side panels, and the 2N inner-layer side panels 212 are grouped into N groups of inner-layer side panels in an arrangement sequence, where N is a positive integer.

When N is equal to 1, a first gap B1 between a first inner-layer side panel C1 and the outer-layer side panel 211 communicates with the inside of the cabinet 21, to form an internal circulation ventilation channel.

When N is greater than 1, a first gap B1 between two neighboring inner-layer side panels 212 in different groups and a first gap B1 between a first inner-layer side panel C1 and the outer-layer side panel 211 communicate with each other, and communicate with the inside of the cabinet 21, to form an internal circulation ventilation channel, and the first inner-layer side panel C1 is an inner-layer side panel that is the farthest from the electronic device 22 in the 2N inner-layer side panels 212.

A second gap B2 between two inner-layer side panels 212 in one group and a second gap B2 between two inner-layer side panels 212 in another group communicate with each other, and communicate with the first air vent A1 and the second air vent A2, to form an external circulation ventilation channel.

It should be noted that FIG. 2A uses a scenario of N=1 as an example and FIG. 2B uses a scenario of N=2 as an example. In this embodiment of this application, a wind direction in the internal circulation ventilation channel may be specifically shown by thick arrows in FIG. 2A and FIG. 2B, and a wind direction in the external circulation ventilation channel may be specifically shown by thin arrows in FIG. 2A and FIG. 2B.

It should be noted that the wind direction in the external circulation ventilation channel may be from bottom to top or from top to bottom, and the wind direction in the internal circulation ventilation channel may be a clockwise direction or a counter-clockwise direction. The wind direction in the external circulation ventilation channel and the wind direction in the internal circulation ventilation channel are not specifically limited in this embodiment of this application. For example, when the external circulation ventilation channel relies on a chimney effect, the wind direction in the external circulation ventilation channel is from bottom to top. Alternatively, when a fan blowing air from top to bottom is added in the external circulation ventilation channel, the wind direction in the external circulation ventilation channel is from top to bottom.

It should be noted that a specific implementation in which the first gap B1 between the two neighboring inner-layer side panels 212 in the different groups communicates with the first gap B1 between the first inner-layer side panel C1 and the outer-layer side panel 211 and a specific implementation in which the second gap B2 between the two inner-layer side panels 212 in one group communicates with the second gap B2 between the two inner-layer side panels 212 in another group are not limited in this embodiment of this application. For example, a plurality of gaps may communicate with each other through another gap, or a plurality of first gaps may communicate with each other through an air deflection structure.

It should be noted that a specific manner in which the first gap B1 communicates with the inside of the cabinet to form the internal circulation ventilation channel is not limited in this embodiment of this application. For example, as shown in FIG. 2A and FIG. 2B, a through hole may be disposed on a panel that is inside the cabinet and that is connected to the electronic device 22, to form the internal circulation ventilation channel. A fan may be disposed between the panel and a top panel of cabinet, to drive air in the internal circulation ventilation channel to flow.

That the height of the first air vent A1 is greater than the height of the second air vent A2 is used as an example. Optionally, the first air vent A1 may be disposed on a top panel of the housing, and the second air vent A2 may be disposed on a bottom panel and/or the outer-layer side panel 211 of the housing. Alternatively, the first air vent A1 may be disposed on the outer-layer side panel 211 of the housing, and the second air vent A2 may be disposed on a bottom panel and/or the outer-layer side panel 211 of the housing.

As shown in FIG. 2A, that N is equal to 1, and the external circulation ventilation channel relies on the chimney effect is used as an example. A heat exchange principle of the heat dissipation structure provided in this embodiment of this application may be specifically as follows:

When hot air in the cabinet 21 reaches the first gap B1 between the first inner-layer side panel C1 and the outer-layer side panel 211, heat may be transferred to the first inner-layer side panel C1 and the outer-layer side panel 211 through convective heat exchange, the outer-layer side panel 211 may directly perform convective heat exchange and radiation heat exchange with outside air, and the first inner-layer side panel C1 may perform convective heat exchange with air in the external circulation ventilation channel. An inner-layer side panel 212 other than the first inner-layer side panel C1 may be in direct contact with the hot air in the cabinet, is directly heated, and then performs convective heat exchange with the air in the external circulation ventilation channel. The air in the external circulation ventilation channel is heated by the inner-layer side panel 212, to form the chimney effect, to drive the hot air in the external circulation ventilation channel to flow out from a relatively high air exhaust vent, and cold air constantly flows in from a relatively low air intake vent, to constantly bring away heat in the cabinet, to implement heat dissipation.

It can be learned from the foregoing heat exchange principle that when N is equal to 1, the heat dissipation structure provided in this embodiment can dissipate heat by using all the three layers of side panels included in the housing.

In this embodiment, when a heat exchange area provided by the 2+1 layers of side panels cannot meet a heat dissipation requirement, an even quantity of inner-layer side panels may be added, that is, N may be increased, to further improve a heat dissipation capability.

As shown in FIG. 2B, that N is equal to 2, and the external circulation ventilation channel relies on the chimney effect is used as an example. A heat exchange principle of the heat dissipation structure in this embodiment of this application may be specifically as follows:

When hot air in the cabinet 21 reaches the first gap B1 between the first inner-layer side panel C1 and the outer-layer side panel 211, heat may be transferred to the first inner-layer side panel C1 and the outer-layer side panel 211 through convective heat exchange, the outer-layer side panel 211 may directly perform convective heat exchange and radiation heat exchange with outside air, and the first inner-layer side panel C1 may perform convective heat exchange with air in the external circulation ventilation channel. When the hot air in the cabinet 21 reaches the first gap B1 between the two neighboring inner-layer side panels 212 in the different groups, heat may be transferred to the two neighboring inner-layer side panels 212 in the different groups through convective heat exchange, and the two neighboring inner-layer side panels 212 in the different groups may perform convective heat exchange with the air in the external circulation ventilation channel. An inner-layer side panel that is the closest to the electronic device 22 may be in direct contact with the hot air in the cabinet, is directly heated, and performs convective heat exchange with the air in the external circulation ventilation channel. The air in the external circulation ventilation channel is heated by the inner-layer side panel 212, to form the chimney effect, to drive the hot air in the external circulation ventilation channel to flow out from a relatively high air exhaust vent, and cold air constantly flows in from a relatively low air intake vent, to constantly bring away heat in the cabinet, to implement heat dissipation.

It can be learned from the foregoing heat exchange principle that when N is greater than 1, the heat dissipation structure provided in this embodiment can dissipate heat by using all the 2N+1 layers of side panels included in the housing.

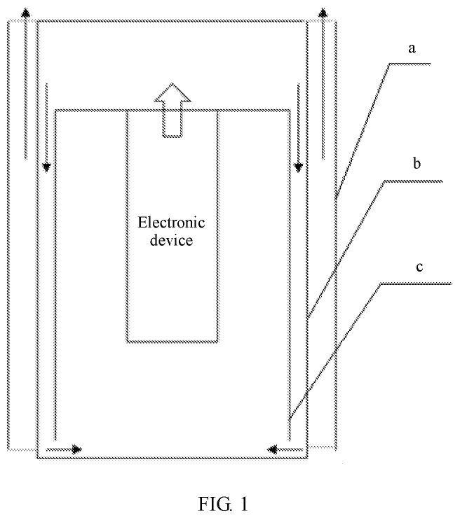

In this embodiment of this application, when N=1, a first gap between an inner-layer side panel that is farther from the electronic device in two inner-layer side panels and the outer-layer side panel communicates with the inside of the cabinet, to form an internal circulation ventilation channel; and a second gap between the two inner-layer side panels communicates with the first air vent and the second air vent, and both the first air vent and the second air vent communicate with the outside of the cabinet, to form an external circulation ventilation channel, so that the external circulation ventilation channel is disposed on an inner side of the internal circulation ventilation channel, to additionally increase a heat exchange area when sizes of side panels of the cabinet are determined. Compared with the heat dissipation structure that is shown in FIG. 1 and that dissipates heat by using only a heat exchange area provided by an intermediate-layer side panel in three layers of side panels, in the heat dissipation structure provided in this embodiment of this application, all the layers of side panels can provide heat dissipation areas, to improve heat dissipation efficiency.

In addition, when N is greater than 1, the 2N inner-layer side panels are grouped into the N groups of inner-layer side panels in the arrangement sequence, and the first gap between the two neighboring inner-layer side panels in the different groups and the first gap between the first inner-layer side panel and the outer-layer side panel communicate with each other, and communicate with the inside of the cabinet, to form the internal circulation ventilation channel; and the second gap between two inner-layer side panels in one group and the second gap between two inner-layer side panels in another group communicate with each other, and communicate with the first air vent and the second air vent, and both the first air vent and the second air vent communicate with the outside of the cabinet, to form the external circulation ventilation channel, so that when a heat exchange area provided by 2+1 layers of side panels cannot meet a heat dissipation requirement, an even quantity of inner-layer side panels may be added, to further improve a heat dissipation capability.

In addition, because the heat dissipation structure provided in this embodiment of this application can improve heat dissipation efficiency without using an extra heat exchange component, the heat dissipation structure provided in this embodiment of this application can reduce costs. Further, because the heat dissipation structure provided in this embodiment of this application can improve heat dissipation efficiency without changing the sizes of the side panels of the cabinet, the heat dissipation structure provided in this embodiment of this application can ensure consistency of appearance of the cabinet.

It should be noted that side panels on any one or more sides of the housing of the cabinet can use the heat dissipation structure provided in this embodiment of this application.

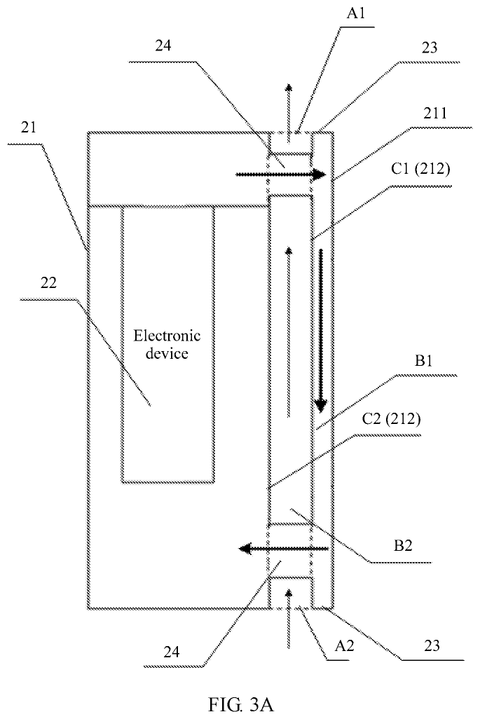

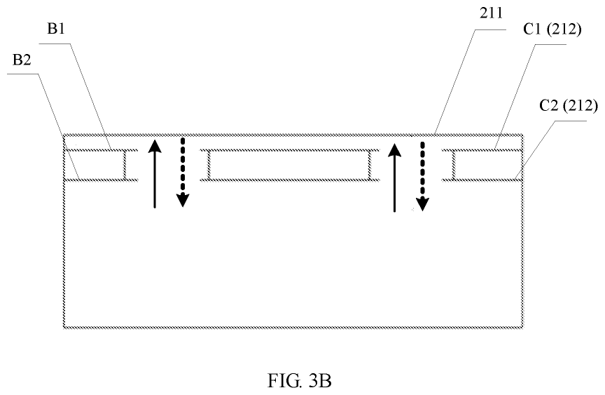

FIG. 3A is a main view of a heat dissipation structure according to another embodiment of this application, and FIG. 3B is a top view of the heat dissipation structure according to the another embodiment of this application. This embodiment mainly describes an optional implementation of forming the internal circulation ventilation channel based on the embodiments shown in FIG. 2A and FIG. 2B. As shown in FIG. 3A and FIG. 3B, the heat dissipation structure in this embodiment may further include air blocking panels 23 and tubular air deflection structures 24.

The air blocking panels 23 are disposed between upper ends of two side panels forming the first gap B1 and between lower ends of the two side panels forming the first gap B1.

A first through hole (not shown) and a second through hole (not shown) that have different heights are disposed on each inner-layer side panel 212, and a first through hole and a second through hole that are disposed on a second inner-layer side panel C2 separately communicate with the inside of the cabinet 21. The second inner-layer side panel C2 is an inner-layer side panel that is the closest to the electronic device 22 in the 2N inner-layer side panels.

The air deflection structure 24 is connected between first through holes of two inner-layer side panels in a same group, and the air deflection structure 24 is connected between second through holes of the two inner-layer side panels in the same group.

It should be noted that one or more first through holes and one or more second through holes may be disposed on a same inner-layer side panel. A same quantity of first through holes and a same quantity of second through holes may be disposed on two inner-layer side panels in a same group. Heights of first through holes disposed on different inner-layer side panels may be the same or may be different, heights of second through holes disposed on different inner-layer side panels may be the same or may be different, and this is not limited in this embodiment of this application.

It should be noted that the two side panels forming the first gap B1 may be the first inner-layer side panel C1 and the outer-layer side panel 211, or may be two neighboring inner-layer side panels 212 in different groups.

It should be noted that FIG. 3A uses an example in which the first air vent A1 is disposed on the top panel of the housing, the second air vent A2 is disposed on the bottom panel of the housing, and N is equal to 1. Thick solid arrows in FIG. 3B may represent a direction of air entering the first gap B1 in the internal circulation ventilation channel, and thick dashed arrows may represent a direction of air exiting from the first gap B1 in the internal circulation ventilation channel. FIG. 3B uses an example in which two first through holes and two second through holes are disposed on a same inner-layer side panel.

As shown in FIG. 3A and FIG. 3B, when N is equal to 1, hot air in the cabinet 21 is led into the first gap B1 between the first inner-layer side panel C1 and the outer-layer side panel 211 through an air deflection structure disposed between upper ends of two inner-layer side panels; and after being cooled through heat exchange, the air is led back into the cabinet 21 through an air deflection structure disposed between lower ends of the two inner-layer side panels.

Optionally, the air deflection structure 24 may be specifically an air deflection twyer. A shape of a cross-section of the air deflection twyer includes but is not limited to a rectangle, a round, an ellipse, a triangle, a polygon, and the like, or is a combination of the foregoing shapes.

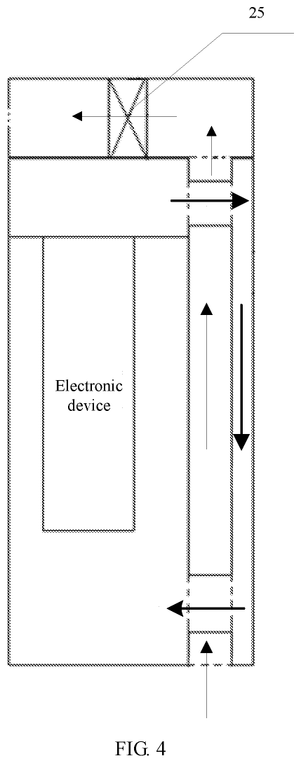

Optionally, as shown in FIG. 4, the heat dissipation structure in this embodiment may further include a fan 25 disposed in the external circulation ventilation channel. In this embodiment, the fan is disposed in the external circulation ventilation channel, so that a flow velocity of air in the external circulation ventilation channel can be greatly increased, and heat dissipation efficiency can be further improved.

It should be noted that FIG. 4 uses an example in which the fan 25 is disposed on a top part of the cabinet, and a location of disposing the fan 25 is not limited in this embodiment. For example, the fan 25 may alternatively be disposed on a bottom part of the cabinet.

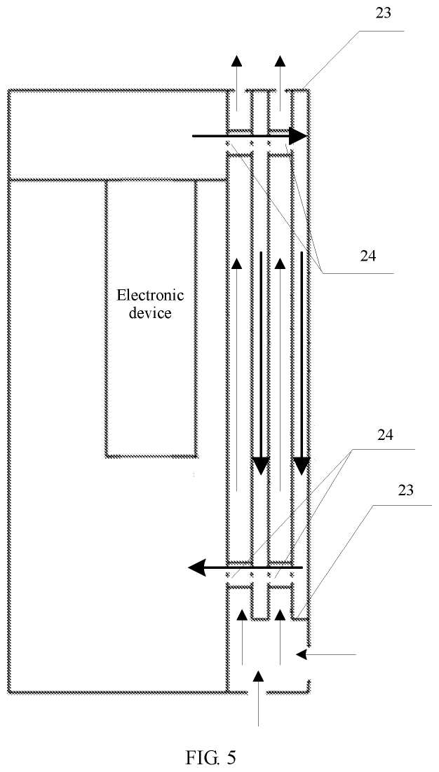

It should be noted that FIG. 3A and FIG. 3B use an example in which the air blocking panel 23 disposed between the upper ends of the two side panels forming the first gap B1 is the top panel of the housing, and the air blocking panel 23 disposed between the lower ends of the two side panels forming the first gap B1 is the bottom panel of the housing. The air blocking panel 23 may alternatively be a panel, other than the top panel and the bottom panel of the housing, disposed and specially used to form a closed internal circulation ventilation channel. For example, as shown in FIG. 5, the air blocking panel 23 disposed between the lower ends of the two side panels forming the first gap B1 may be a panel, other than the top panel and the bottom panel of the housing, disposed and specially used to form a closed internal circulation ventilation channel. A person skilled in the art may understand that the air blocking panel 23 disposed between the upper ends of the two side panels forming the first gap B1 may alternatively be a panel, other than the top panel and the bottom panel of the housing, disposed and specially used to form a closed internal circulation ventilation channel.

It should be noted that FIG. 5 uses an example in which the first air vent A1 is disposed on the top panel of the housing, the second air vent A2 is disposed on the bottom panel and the outer-layer side panel 211 of the housing, and N is equal to 2.

As shown in FIG. 5, when N is equal to 2, hot air in the cabinet 21 is led into the first gap B1 between the first inner-layer side panel C1 and the outer-layer side panel 211 and the first gap B1 between the two inner-layer side panels in the different groups through the air deflection structure disposed between the first through holes of the two inner-layer side panels in the same group; and after being cooled through heat exchange, the air is led back into the inside of the cabinet 21 through the air deflection structure disposed between the second through holes of the two inner-layer side panels in the same group.

As shown in FIG. 3A to FIG. 5, a quantity of air deflection structures 24 in this embodiment is at least 2N. A specific quantity of air deflection structures 24 is not limited in this embodiment, and the quantity of air deflection structures may be flexibly set provided that at least one air deflection structure is used to lead the hot air into the cabinet 21 to the first gap and at least one air deflection structure is used to lead the cold air that is cooled through heat exchange back into the inside of the cabinet 21.

In this embodiment, the air blocking panels are disposed between the upper ends of the two side panels forming the first gap and between the lower ends of the two side panels forming the first gap, the first through hole and the second through hole that have different heights are disposed on each inner-layer side panel, and both the first through hole and the second through hole disposed on the second inner-layer side panel communicate with the inside of the cabinet. The second inner-layer side panel is an inner-layer side panel that is the closest to the electronic device in the 2N inner-layer side panels, the air deflection structure is connected between the first through holes of the two inner-layer side panels in the same group, and the air deflection structure is connected between the second through holes of the two inner-layer side panels in the same group, so that the first gap between the two neighboring inner-layer side panels in the different groups and the first gap between the first inner-layer side panel and the outer-layer side panel communicate with each other, and communicate with the first through hole and the second through hole, to form the internal circulation ventilation channel.

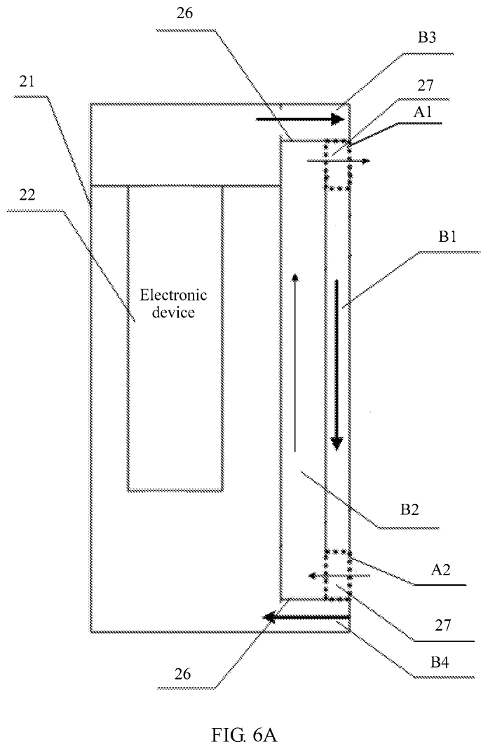

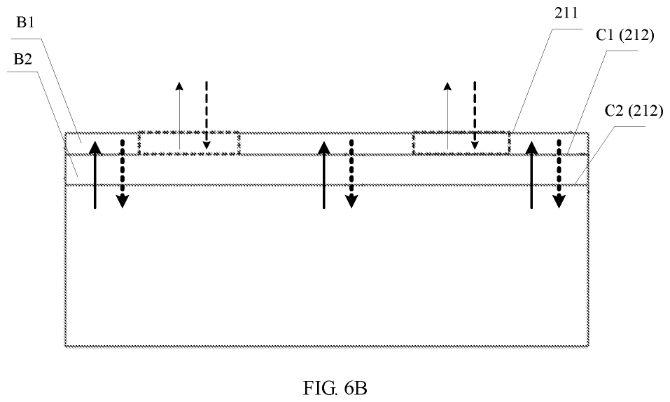

FIG. 6A is a main view of a heat dissipation structure according to still another embodiment of this application, and FIG. 6B is a top view of the heat dissipation structure according to the still another embodiment of this application. This embodiment mainly describes another optional implementation of forming the internal circulation ventilation channel based on the embodiments shown in FIG. 2A and FIG. 2B. As shown in FIG. 6A and FIG. 6B, the heat dissipation structure in this embodiment may further include air blocking panels 26.

The air blocking panels 26 are disposed between upper ends of two inner-layer side panels 212 forming the second gap B2 and between lower ends of the two inner-layer side panels forming the second gap B2.

There is a third gap B3 between upper ends of side panels forming a first gap B1 and a top panel of the housing, there is a fourth gap B4 between lower ends of the side panels forming the first gap B1 and a bottom panel of the housing, and both the third gap B3 and the fourth gap B4 communicate with the inside of the cabinet 21.

It should be noted that the two side panels forming the second gap B2 may be specifically two inner-layer side panels 212 in a same group. FIG. 6A and FIG. 6B use an example in which N is equal to 1. Thick solid arrows in FIG. 6B may represent a direction of air entering the first gap B1 in the internal circulation ventilation channel, and thick dashed arrows may represent a direction of air exiting from the first gap B1 in the internal circulation ventilation channel.

As shown in FIG. 6A and FIG. 6B, when N is equal to 1, hot air in the cabinet 21 enters the first gap B1 between the first inner-layer side panel C1 and the outer-layer side panel 211 through the third gap B3 between the upper ends of the side panels forming the first gap B1 and the top panel of the housing; and after being cooled through heat exchange, the air is led back into the inside of the cabinet 21 through the fourth gap B4 between the lower ends of the side panels forming the first gap B1 and the bottom panel of the housing.

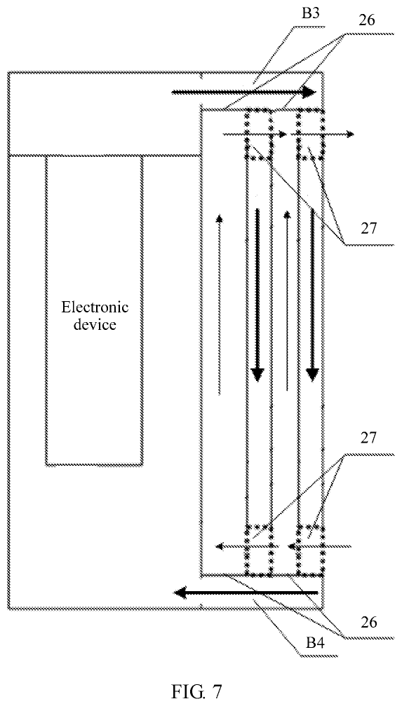

In this embodiment, when N is equal to 2, a schematic structural diagram of the heat dissipation structure may be shown in FIG. 7.

Optionally, as shown in FIG. 6A to FIG. 7, both the first air vent A1 and the second air vent A2 may be disposed on the outer-layer side panel 211. The heat dissipation structure may further include tubular air deflection structures 27.

A third through hole (not shown) and a fourth through hole (not shown) that have different heights are disposed on an inner-layer side panel other than a second inner-layer side panel C2 in the 2N inner-layer side panels 212, and the second inner-layer side panel C2 is an inner-layer side panel that is the closest to the electronic device 22 in the 2N inner-layer side panels.

It should be noted that one or more third through holes and one or more fourth through holes may be disposed on a same inner-layer side panel. A same quantity of third through holes and a same quantity of fourth through holes may be disposed on two inner-layer side panels in a same group. Heights of third through holes disposed on different inner-layer side panels may be the same or may be different, heights of fourth through holes disposed on different inner-layer side panels may be the same or may be different, and this is not limited in this embodiment of this application. Heights of a third through hole disposed on the first inner-layer side panel and the first air vent A1 may be the same or may be different, and this is not limited in this embodiment of this application. Heights of a fourth through hole disposed on the first inner-layer side panel and the second air vent A2 may be the same or may be different, and this is not limited in this embodiment of this application.

It should be noted that thin solid arrows in FIG. 6B may represent a direction of air entering the second gap B2 in the external circulation ventilation channel, and thin dashed arrows may represent a direction of air exiting from the second gap B2 in the external circulation ventilation channel. FIG. 6B uses an example in which two third through holes and two fourth through holes are disposed on a same inner-layer side panel.

As shown in FIG. 6A and FIG. 6B, when N is equal to 1, the air deflection structure 27 is connected between the third through hole of the first inner-layer side panel C1 and the first air vent A1, and the air deflection structure 27 is connected between the fourth through hole of the first inner-layer side panel C1 and the second air vent A2.

Specifically, as shown in FIG. 6A and FIG. 6B, when N is equal to 1, cold air outside the cabinet may be led into the second gap B2 between the two inner-layer side panels in the same group through the air deflection structure 27 disposed between the fourth through hole of the first inner-layer side panel C1 and the second air vent A2; and after being heated by the inner-layer side panels, the air is led out through the air deflection structure 27 disposed between the third through hole of the first inner-layer side panel C1 and the first air vent A1.

As shown in FIG. 7, when N is greater than 1, the air deflection structure 27 is connected between the third through hole of the first inner-layer side panel C1 and the first air vent A1, the air deflection structure 27 is connected between the fourth through hole of the first inner-layer side panel C1 and the second air vent A2, the air deflection structure 27 is connected between third through holes of two neighboring inner-layer side panels in different groups, and the air deflection structure 27 is connected between fourth through holes of the two neighboring inner-layer side panels in the different groups.

Specifically, as shown in FIG. 7, when N is greater than 1, cold air outside the cabinet may be led into the second gap B2 between the two inner-layer side panels in the same group through the air deflection structure 27 disposed between the fourth through hole of the first inner-layer side panel C1 and the second air vent A2 and the air deflection structure 27 disposed between the fourth through holes of the two neighboring inner-layer side panels in the different groups; and after being heated by the inner-layer side panels, the air is led out through the air deflection structure 27 disposed between the third through hole of the first inner-layer side panel C1 and the first air vent A1 and the air deflection structure 27 disposed between the third through holes of the two neighboring inner-layer side panels in the different groups.

Optionally, the air deflection structure 27 may be specifically an air deflection twyer. A shape of a cross-section of the air deflection twyer includes but is not limited to a rectangle, a round, an ellipse, a triangle, a polygon, and the like, or is a combination of the foregoing shapes.

Optionally, the heat dissipation structure in this embodiment may further include a fan (not shown) disposed in the external circulation ventilation channel. In this embodiment, the fan is disposed in the external circulation ventilation channel, so that a flow velocity of air in the external circulation ventilation channel can be greatly increased, and heat dissipation efficiency can be further improved. A location of disposing the fan is not limited in this embodiment. For example, the fan may be disposed on a top part or a bottom part of the cabinet 21.

As shown in FIG. 6A to FIG. 7, a quantity of air deflection structures 27 in this embodiment is at least 2N. A specific quantity of air deflection structures 27 is not limited in this embodiment, and the quantity of air deflection structures may be flexibly set provided that at least one air deflection structure is used to lead the cold air outside the cabinet 21 into the second gap and at least one air deflection structure is used to lead the hot air that is heated through heat exchange out to the outside of the cabinet 21.

In this embodiment, the air blocking panels are disposed between the upper ends of the two inner-layer side panels forming the second gap and between the lower ends of the two inner-layer side panels forming the second gap, there is the third gap between the upper ends of the side panels forming the first gap and the top panel of the housing, there is the fourth gap between the lower ends of the side panels forming the first gap and the bottom panel of the housing, and both the third gap and the fourth gap communicate with the inside of the cabinet, so that the first gap between the two neighboring inner-layer side panels in the different groups and the first gap between the first inner-layer side panel and the outer-layer side panel communicate with each other, and communicate with the inside of the cabinet, to form the internal circulation ventilation channel.

Optionally, in the foregoing embodiments of this application, the side panels may include smooth panels, corrugated panels, or the like. Herein, the side panel may be specifically the inner-layer side panel or the outer-layer side panel.

Optionally, in the foregoing embodiments of this application, gilled structures or flow disturbing structures may be further disposed on the side panels. The gilled structures or the flow disturbing structures are further disposed on the side panels, so that heat dissipation capabilities of the side panels themselves can be improved, and heat dissipation efficiency can be further improved.

It should be noted that specific forms of the gilled structures or the flow disturbing structures are not limited in this embodiment of this application. For example, the gilled structures or the flow disturbing structures may be triangular winglets, rectangular wings, semi-ellipse wings, or the like, or a combination of several of the foregoing structure forms.

An embodiment of this application further provides a cabinet. The cabinet includes a fan and the heat dissipation structure described in any one of the foregoing embodiments, and the fan is disposed in an internal circulation ventilation channel of the heat dissipation structure.

In this embodiment of this application, when N=1, a first gap between an inner-layer side panel that is farther from an electronic device in two inner-layer side panels and an outer-layer side panel communicates with the inside of the cabinet, to form the internal circulation ventilation channel; and a second gap between the two inner-layer side panels communicates with a first air vent and a second air vent, and both the first air vent and the second air vent communicate with the outside of the cabinet, to form an external circulation ventilation channel, so that the external circulation ventilation channel is disposed on an inner side of the internal circulation ventilation channel, to additionally increase a heat exchange area when a size of the cabinet is determined. Compared with the heat dissipation structure that is shown in FIG. 1 and that dissipates heat by using only a heat exchange area provided by an intermediate-layer side panel in three layers of side panels, in the cabinet provided in this embodiment of this application, all layers of side panels can provide heat dissipation areas, to improve heat dissipation efficiency of the cabinet.

In addition, when N is greater than 1, 2N inner-layer side panels are grouped into N groups of inner-layer side panels in an arrangement sequence, a first gap between two neighboring inner-layer side panels in different groups and a first gap between a first inner-layer side panel and an outer-layer side panel communicate with each other, and communicate with the inside of the cabinet, to form the internal circulation ventilation channel; and second gaps, each of which is between two inner-layer side panels in a same group, communicate with each other, and communicate with a first air vent and a second air vent, and both the first air vent and the second air vent communicate with the outside of the cabinet, to form an external circulation ventilation channel, so that when a heat exchange area provided by 2+1 layers of side panels cannot meet a heat dissipation requirement, an even quantity of inner-layer side panels may be added, to further improve a heat dissipation capability of the cabinet.

In addition, because the cabinet provided in this embodiment of this application can improve heat dissipation efficiency without using an extra heat exchange component, the cabinet provided in this embodiment of this application can reduce costs. Further, because the cabinet provided in this embodiment of this application can improve heat dissipation efficiency without changing sizes of side panels of the cabinet, the cabinet provided in this embodiment of this application can ensure consistency of appearance of the cabinet.

An embodiment of this application further provides a communications system. The communications system includes the cabinet described in the foregoing embodiments and an electronic device mounted inside the cabinet.

What is claimed is:

1. A heat dissipation structure, configured to dissipate heat for an electronic device mounted inside a cabinet, and comprising a housing of the cabinet, wherein
a first air vent and a second air vent that have different heights are disposed on the housing, and both the first air vent and the second air vent communicate with the outside of the cabinet;
the housing comprises 2N+1 layers of side panels, the 2N+1 layers of side panels comprise an outer-layer side panel and 2N inner-layer side panels, there is a gap between two neighboring side panels, and the 2N inner-layer side panels are grouped into N groups of inner-layer side panels in an arrangement sequence, wherein N is a positive integer;
when N is equal to 1, a first gap between a first inner-layer side panel and the outer-layer side panel communicates with the inside of the cabinet, to form an internal circulation ventilation channel; or
when N is greater than 1, a first gap between two neighboring inner-layer side panels in different groups and a first gap between the first inner-layer side panel and the outer-layer side panel communicate with each other, and communicate with the inside of the cabinet, to form an internal circulation ventilation channel, and the first inner-layer side panel is an inner-layer side panel that is the farthest from the electronic device in the 2N inner-layer side panels; and
second gaps, each of which is between two inner-layer side panels in a same group, communicate with each other, and communicate with the first air vent and the second air vent, to form an external circulation ventilation channel.

2. The heat dissipation structure according to claim 1, wherein the heat dissipation structure further comprises air blocking panels and tubular air deflection structures;
the air blocking panels are disposed between upper ends of two side panels forming the first gap and between lower ends of the two side panels forming the first gap;
a first through hole and a second through hole that have different heights are disposed on each inner-layer side panel, a first through hole and a second through hole that are disposed on a second inner-layer side panel separately communicate with the inside of the cabinet, and the second inner-layer side panel is an inner-layer side panel that is the closest to the electronic device in the 2N inner-layer side panels; and
the air deflection structure is connected between first through holes of two inner-layer side panels in a same group, and the air deflection structure is connected between second through holes of the two inner-layer side panels in the same group.

3. The heat dissipation structure according to claim 2, wherein the first air vent is disposed on a top panel of the housing, and the second air vent is disposed on a bottom panel and/or the outer-layer side panel of the housing; or the first air vent is disposed on the outer-layer side panel of the housing, and the second air vent is disposed on a bottom panel and/or the outer-layer side panel of the housing.

4. The heat dissipation structure according to claim 2, wherein the air blocking panels comprise the top panel and/or the bottom panel of the housing.

5. The heat dissipation structure according to claim 1, wherein the heat dissipation structure further comprises air blocking panels;
the air blocking panels are disposed between upper ends of two inner-layer side panels forming the second gap and between lower ends of the two inner-layer side panels forming the second gap; and
there is a third gap between upper ends of side panels forming the first gap and a top panel of the housing, there is a fourth gap between lower ends of the side panels forming the first gap and a bottom panel of the housing, and both the third gap and the fourth gap communicate with the inside of the cabinet.

6. The heat dissipation structure according to claim 5, wherein both the first air vent and the second air vent are disposed on the outer-layer side panel, and the heat dissipation structure further comprises tubular air deflection structures;
a third through hole and a fourth through hole that have different heights are disposed on an inner-layer side panel other than a second inner-layer side panel in the 2N inner-layer side panels, and the second inner-layer side panel is an inner-layer side panel that is the closest to the electronic device in the 2N inner-layer side panels; and
when N is equal to 1, the air deflection structure is connected between a third through hole of the first inner-layer side panel and the first air vent, and the air deflection structure is connected between a fourth through hole of the first inner-layer side panel and the second air vent; or
when N is greater than 1, the air deflection structure is connected between a third through hole of the first inner-layer side panel and the first air vent, the air deflection structure is connected between a fourth through hole of the first inner-layer side panel and the second air vent, the air deflection structure is connected between third through holes of two neighboring inner-layer side panels in different groups, and the air deflection structure is connected between fourth through holes of the two neighboring inner-layer side panels in the different groups.

7. The heat dissipation structure according to claim 1, wherein the heat dissipation structure further comprises a fan disposed in the external circulation ventilation channel.

8. The heat dissipation structure according to claim 1, wherein the side panels comprise smooth panels or corrugated panels.

9. The heat dissipation structure according to claim 8, wherein gilled structures or flow disturbing structures are further disposed on the side panels.

10. A cabinet, comprising a fan and a heat dissipation structure configured to dissipate heat for an electronic device mounted inside a cabinet, and the heat dissipation structure comprises a housing of the cabinet, wherein
a first air vent and a second air vent that have different heights are disposed on the housing, and both the first air vent and the second air vent communicate with the outside of the cabinet;
the housing comprises 2N+1 layers of side panels, the 2N+1 layers of side panels comprise an outer-layer side panel and 2N inner-layer side panels, there is a gap between two neighboring side panels, and the 2N inner-layer side panels are grouped into N groups of inner-layer side panels in an arrangement sequence, wherein N is a positive integer;
when N is equal to 1, a first gap between a first inner-layer side panel and the outer-layer side panel communicates with the inside of the cabinet, to form an internal circulation ventilation channel; or
when N is greater than 1, a first gap between two neighboring inner-layer side panels in different groups and a first gap between the first inner-layer side panel and the outer-layer side panel communicate with each other, and communicate with the inside of the cabinet, to form an internal circulation ventilation channel, and the first inner-layer side panel is an inner-layer side panel that is the farthest from the electronic device in the 2N inner-layer side panels; and
second gaps, each of which is between two inner-layer side panels in a same group, communicate with each other, and communicate with the first air vent and the second air vent, to form an external circulation ventilation channel.

11. The cabinet according to claim 10, wherein the heat dissipation structure further comprises air blocking panels and tubular air deflection structures;
the air blocking panels are disposed between upper ends of two side panels forming the first gap and between lower ends of the two side panels forming the first gap;
a first through hole and a second through hole that have different heights are disposed on each inner-layer side panel, a first through hole and a second through hole that are disposed on a second inner-layer side panel separately communicate with the inside of the cabinet, and the second inner-layer side panel is an inner-layer side panel that is the closest to the electronic device in the 2N inner-layer side panels; and
the air deflection structure is connected between first through holes of two inner-layer side panels in a same group, and the air deflection structure is connected between second through holes of the two inner-layer side panels in the same group.

12. The cabinet according to claim 11, wherein the first air vent is disposed on a top panel of the housing, and the second air vent is disposed on a bottom panel and/or the outer-layer side panel of the housing; or the first air vent is disposed on the outer-layer side panel of the housing, and the second air vent is disposed on a bottom panel and/or the outer-layer side panel of the housing.

13. The cabinet according to claim 11, wherein the air blocking panels comprise the top panel and/or the bottom panel of the housing.

14. The cabinet according to claim 10, wherein the heat dissipation structure further comprises air blocking panels;
the air blocking panels are disposed between upper ends of two inner-layer side panels forming the second gap and between lower ends of the two inner-layer side panels forming the second gap; and
there is a third gap between upper ends of side panels forming the first gap and a top panel of the housing, there is a fourth gap between lower ends of the side panels forming the first gap and a bottom panel of the housing, and both the third gap and the fourth gap communicate with the inside of the cabinet.

15. A communications system, comprising a cabinet and an electronic device mounted inside the cabinet;
wherein, the cabinet comprises a fan and a heat dissipation structure configured to dissipate heat for an electronic device mounted inside a cabinet, and the heat dissipation structure comprises a housing of the cabinet, wherein
a first air vent and a second air vent that have different heights are disposed on the housing, and both the first air vent and the second air vent communicate with the outside of the cabinet;
the housing comprises 2N+1 layers of side panels, the 2N+1 layers of side panels comprise an outer-layer side panel and 2N inner-layer side panels, there is a gap between two neighboring side panels, and the 2N inner-layer side panels are grouped into N groups of inner-layer side panels in an arrangement sequence, wherein N is a positive integer;
when N is equal to 1, a first gap between a first inner-layer side panel and the outer-layer side panel communicates with the inside of the cabinet, to form an internal circulation ventilation channel; or
when N is greater than 1, a first gap between two neighboring inner-layer side panels in different groups and a first gap between the first inner-layer side panel and the outer-layer side panel communicate with each other, and communicate with the inside of the cabinet, to form an internal circulation ventilation channel, and the first inner-layer side panel is an inner-layer side panel that is the farthest from the electronic device in the 2N inner-layer side panels; and
second gaps, each of which is between two inner-layer side panels in a same group, communicate with each other, and communicate with the first air vent and the second air vent, to form an external circulation ventilation channel.
